(19) United States
(12) Patent Application Publication
(10) Pub. No.: US 2025/0169049 A1
(43) Pub. Date: May 22, 2025

(54) SEMICONDUCTOR STRUCTURE INCLUDING TRANSISTOR WITH DIFFERENT CHANNEL LENGTHS AND METHOD FOR MANUFACTURING THE SAME

(71) Applicant: Taiwan Semiconductor Manufacturing Company, Ltd., Hsinchu (TW)

(72) Inventor: Chih-Yang Chen, Hsinchu (TW)

(73) Assignee: Taiwan Semiconductor Manufacturing Company, Ltd., Hsinchu (TW)

(21) Appl. No.: 18/511,279

(22) Filed: Nov. 16, 2023

(51) Int. Cl. H10B 10/00; H01L 29/06; H01L 29/08; H01L 29/423; H01L 29/66; H01L 29/775; H01L 29/786

(52) U.S. Cl. CPC H10B 10/125; H10D 30/014; H10D 30/43; H10D 30/6735; H10D 30/6757; H10D 62/121; H10D 62/151; H10D 64/017; H10D 64/018

(57) ABSTRACT

A method for manufacturing a semiconductor structure includes: forming a first patterned structure on a memory region of a base structure and forming a second patterned structure and a third patterned structure on a logic region of the base structure, the first patterned structure including a first channel portion, the second patterned structure including a second channel portion, the third patterned structure including a third channel portion, each of the first, second and third channel portions having two exposed end surfaces which are opposite to each other; forming a patterned hard mask covering the first and third patterned structures; and performing an etching process through the patterned hard mask so as to reduce a minimum distance between the two exposed end surfaces of the second channel portion.

### BACKGROUND

Nowadays, integrated circuits (ICs) are used in consumer electronics products and automotive electronics products. Transistors are key active components in modern ICs. In order to manufacture electronics products with relatively lower power consumption, longer service lifetime, higher computing speed, and so on, many approaches are being continuously developed for optimizing each of the transistors in the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic sectional view illustrating a semiconductor structure in accordance with some embodiments.

FIG. 1B is a schematic top view of the semiconductor structure in FIG. 1A in accordance with some embodiments.

FIG. 1C is a schematic sectional view taken along line A-A of FIG. 1A in accordance with some embodiments.

FIG. 1D is a schematic top view of a static random-access memory (SRAM) cell in accordance with some embodiments.

FIGS. 2A, 2B and 2C are fragmentary enlarged perspective views respectively illustrating details regarding an area Z1 of a first transistor, an area Z2 of a second transistor and an area Z3 of a third transistor in FIG. 1A in accordance with some embodiments.

FIG. 3 is a flow diagram illustrating a method for manufacturing a semiconductor structure including a plurality of transistors in accordance with some embodiments.

FIGS. 4 to 20 illustrate schematic views of intermediate stages of the method depicted in FIG. 3 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In general, an integrated circuit may include a plurality of transistors. For each of the transistors, a channel extends between two source/drain portions in a first direction. The channel has a channel length in the first direction and a channel width in a second direction transverse to the first direction. In order to boost device performance (e.g., higher saturation drain current (Ids) in a channel, higher speed, higher frequency) for each of the transistors, the channel length in each of the transistors may be reduced, whereas a gate length (Lg) of a gate electrode in the first direction is not changed. In such case, as the device performance is improved, a leakage current between the gate electrode and one of the two source/drain portions may be inevitably increased. In practice, ultra-low leakage current may be a primary specification to be met for some of the transistors, and high saturation drain current may be another primary specification to be met for the some other transistors. Therefore, the present disclosure is directed to a semiconductor structure including at least one high performance transistor, at least one low power transistor, and a memory cell together integrated to be formed on the same substrate.

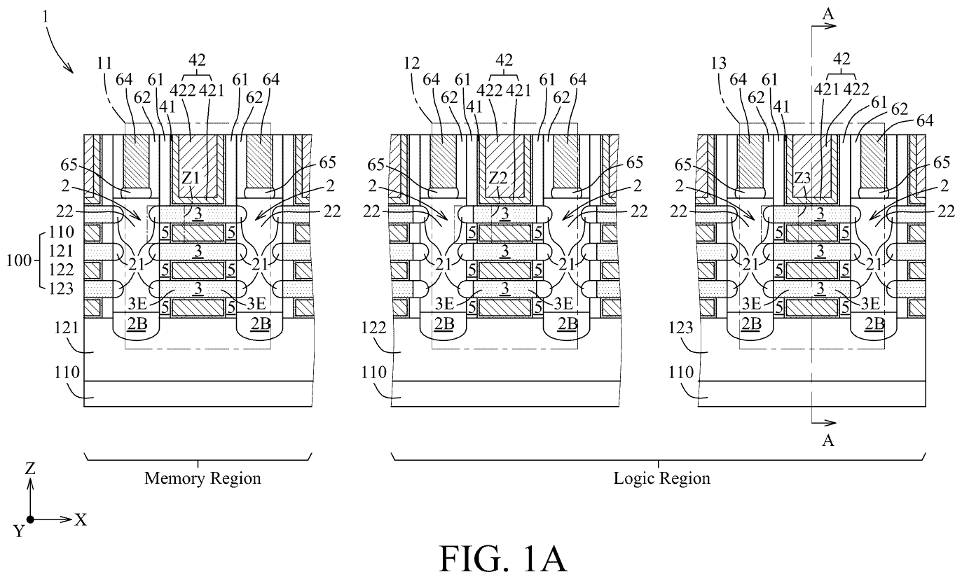

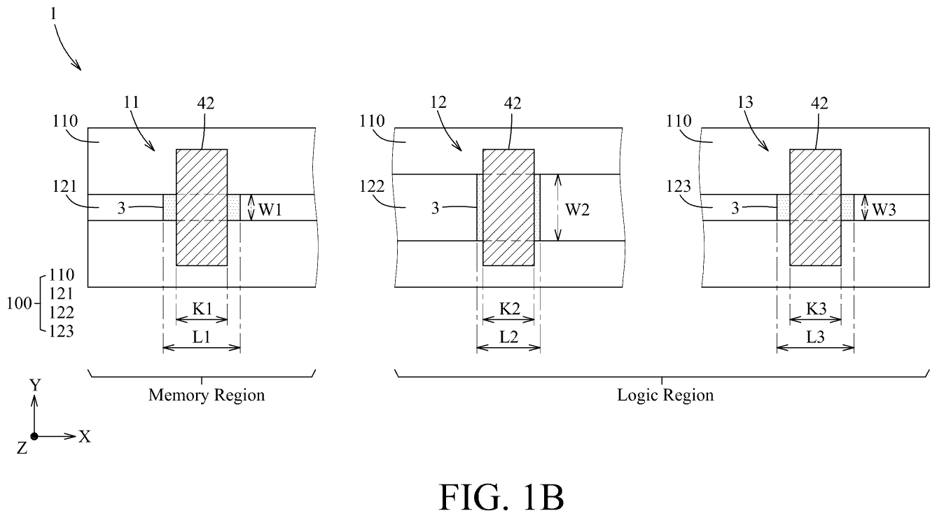

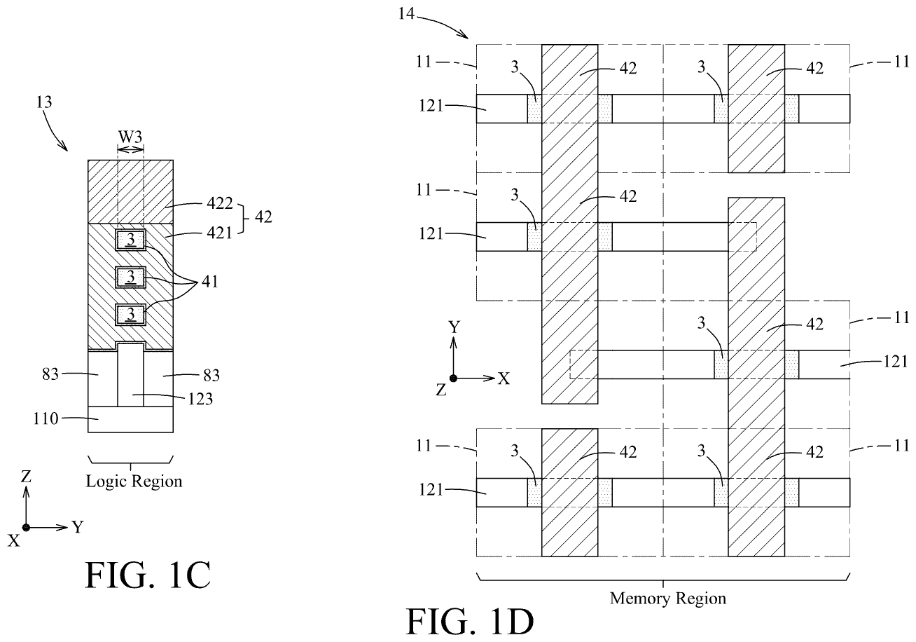

FIG. 1A is a schematic sectional view illustrating a semiconductor structure 1 in accordance with some embodiments. FIG. 1B is a schematic top view of the semiconductor structure 1 in accordance with some embodiments, in which a substrate 100, and a gate electrode 42 and an uppermost one of channel portions 3 in each of transistors 11, 12, 13 are shown, and other elements are omitted for the sake of clarity and brevity. FIG. 1C is a schematic sectional view taken along line A-A of FIG. 1A in accordance with some embodiments.

The semiconductor structure 1 includes a substrate 100, multiple first transistors 11 (one of which is shown in FIGS. 1A and 1B) disposed on a memory region of the substrate 100, and a second transistor 12 and a third transistor 13 disposed on a logic region of the substrate 100.

In some embodiments, the substrate 100 includes elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In addition, the substrate 100 may be a bulk silicon substrate, a silicon-on-insulator (SOI) substrate, or a germanium-on-insulator (GOI) substrate. Other materials or configurations suitable for the substrate 100 are within the contemplated scope of the present disclosure. The substrate 100 includes an underlying portion 110 and multiple fin portions disposed on the underlying portion 110. The fin portions include multiple first fin portions 121 (one of which is shown in FIG. 1A, and four of which are shown in FIG. 1D), a second fin portion 122 and a third fin portion 123. The first fin portions 121 are located at the memory region, and the second and third fin portions 122, 123 are located at the logic region. In some embodiments, each of the fin portions 121, 122, 123 may be doped with n-type impurities to form an n-well when p-type devices (e.g., p-type metal-oxide-semiconductor transistor, PMOS) are designed to be formed thereon, or may be doped with p-type impurities to form a p-well when n-type devices (e.g., n-type metal-oxide-semiconductor transistor, NMOS) are designed to be formed thereon.

Referring to FIGS. 1A and 1B, the memory region and the logic region of the substrate 100 are displaced from each other. The memory region is designed for forming memory cells thereon. FIG. 1D is a schematic top view of a static random-access memory (SRAM) cell 14 in accordance with some embodiments. As shown in FIG. 1D, the SRAM cell 14 includes six of the first transistors 11 (one of which is also shown in FIGS. 1A and 1B) coupled to each other, and is capable of storing binary information. The binary information may be written into or read from the SRAM cell 14 through bit lines (not shown). In FIG. 1D, the gate electrode 42 and an uppermost one of channel portions 3 in each of the first transistors 11 are shown, and other elements are omitted for the sake of clarity and brevity. Each of the six first transistors 11 is formed on a corresponding one of the first fin portions 121. In some embodiments, two adjacent ones of the first transistors 11 may be formed on the same first fin portion 121. The gate electrodes 42 of two adjacent ones of the first transistors 11 may be connected to or separated from each other according to circuit design of the SRAM cell 14. The logic region is designed for forming logic circuits thereon. The logic circuits include the second transistor 12 and the third transistor 13. Each of the logic circuits has a function different from the function of the SRAM cell 14.

Referring to FIGS. 1A and 1C, each of the first transistors 11, the second transistor 12 and the third transistor 13 is configured as a gate-all-around field-effect transistor (GAAFET), and includes two source/drain portions 2 (see FIG. 1A), at least one channel portion (three channel portions 3 are exemplarily shown in FIGS. 1A and 1C), at least one pair of inner spacers (three pairs of inner spacers 5 are exemplarily shown in FIG. 1A), a gate dielectric layer 41, and a gate electrode 42 which is isolated from the at least one channel portion through the gate dielectric layer 41. In some other embodiments not shown herein, each of the transistors 11, 12, 13 may be configured as a part of a complementary field-effect transistors (CFET) structure which includes two GAAFETs stacked on one another in a Z direction, or configured as a part of a fork-sheet structure which includes two GAAFETs spaced part from each other in a Y direction transverse to the Z direction through a wall portion. According to the circuit design of the semiconductor structure 1, the first transistors 11 each may be designed to be an n-FET or a p-FET, and the second and third transistors 12, 13 each may be designed to be an n-FET or a p-FET.

Referring to FIG. 1A, in each of the transistors 11, 12, 13, the three channel portions 3 are spaced apart from each other in the Z direction, and a bottommost one of the three channel portions 3 is spaced apart from the substrate 100 in the Z direction. In some embodiments, each of the three channel portions 3 includes a semiconductor material. In some embodiments, possible semiconductor materials suitable for the three channel portions 3 are similar to those for the substrate 100, and thus the details thereof are omitted for the sake of brevity. In some embodiments, each of the three channel portions 3 includes silicon. Other semiconductor materials suitable for the three channel portions 3 are within the contemplated scope of the present disclosure. In some embodiments, each of the three channel portions 3 may have a thickness in the Z direction ranging from about 3 nm to about 8 nm, but other ranges of value are also within the contemplated scope of the present disclosure. In some embodiments, two adjacent ones of the channel portions 3 are spaced apart from each other in the Z direction by a distance ranging from about 5 nm to about 12 nm, but other ranges of value are also within the contemplated scope of the present disclosure. It is noted that the number of the channel portions 3 in each of the transistors 11, 12, 13 is not limited to three as shown in FIG. 1A, and may also be one, two, four or more. In addition, in some embodiments not shown herein, the number (or thickness) of the channel portions 3 in the first transistors 11, the number (or thickness) of the channel portions 3 in the second transistor 12 and the number (or thickness) of the channel portions 3 in the third transistor 13 may be different from each other.

Referring to FIG. 1B, each of the channel portions 3 of the first transistor 11 has a width W1 in the Y direction, and a length L1 in the X direction. Each of the channel portions 3 of the second transistor 12 has a width W2 in the Y direction, and a length L2 in the X direction. Each of the channel portions 3 of the third transistor 13 has a width W3 (see also FIG. 1C) in the Y direction, and a length L3 in the X direction. The width W2 is greater than each of the width W1 and the width W3. In some embodiments, the width W2 may range from about 17 nm to about 100 nm. In some embodiments, each of the width W1 and the width W3 may be less than about 17 nm (e.g., each of W1 and W3 may be greater than 0 nm and less than about 17 nm, or may be greater than 0 nm and less than about 13 nm). The width W1 may be the same as or different from the width W3.

In each of the transistors 11, 12, 13, as shown in FIG. 1A, the two source/drain portions 2 are spaced apart from each other in an X direction transverse to the Y direction and the Z direction, such that each of the three channel portions 3 extends between the two source/drain portions 2 to terminate at two channel ends 3E. In some embodiments, the X, Y and Z directions are perpendicular to each other.

In some embodiments, each of the two source/drain portions 2 may include a group IV semiconductor material such as single crystalline silicon, polycrystalline silicon, single crystalline silicon germanium, polycrystalline silicon germanium, other suitable materials, or combinations thereof. In some embodiments, each of the two source/drain portions 2 may be doped with group V impurities (which may be also referred to as n-type impurities) so as to function as a source/drain of an n-FET. The n-type impurities may be, for example, but not limited to, nitrogen (N), phosphorous (P), arsenic (As), antimony (Sb), other suitable materials, or combinations thereof. In some other embodiments, each of the two source/drain portions 2 may be doped with group III impurities (which may be also referred to as p-type impurities) so as to function as a source/drain of a p-FET. The p-type impurities may be, for example, but not limited to, boron (B), aluminum (Al), gallium (Ga), indium (In), other suitable materials, or combinations thereof. In some embodiments, each of the two source/drain portions 2 may be formed as a multi-layered structure. As shown in FIG. 1A, each of the two source/drain portions 2 may have three first regions 21 disposed to be respectively in contact with the three channel portions 3, and a second region 22 disposed to cover the three first regions 21. As such, the second region 22 is separated from the three channel portions 3 through the three first regions 21, respectively. The n-type (or p-type) impurities in the second region 22 may be the same as or different from the n-type (or p-type) impurities in each of the first regions 21. The n-type (or p-type) impurities in the second region 22 may have a doping concentration different from a doping concentration of the n-type (or p-type) impurities in each of the first regions 21. For example, in the case that each of the two source/drain portions 2 is a source/drain of an n-FET, each of the first and second regions 21, 22 may be made of silicon doped with n-type impurities. The n-type impurities doped in each of the first regions 21 are different from the n-type impurities doped in the second region 22, and the second region 22 has a doping concentration greater than the doping concentration of each of the first regions 21. In the case that each of the two source/drain portions 2 is a source/drain of a p-FET, each of the first regions 21 may be made of silicon doped with p-type impurities, and the second region 22 may be made of silicon germanium doped with p-type impurities. The p-type impurities doped in each of the first regions 21 are the same as the p-type impurities doped in the second region 22, and the second region 22 has a doping concentration greater than the doping concentration of each of the first regions 21. In some other embodiments not shown herein, each of the source/drain portions 2 may be formed as a single layer structure. In some embodiments, each of the two source/drain portions 2 further includes a bottom region 2B disposed beneath the second region 22. The bottom region 2B may be formed as a single layer structure, a bi-layered structure or a multi-layered structure. In some embodiments, the bottom region 2B may include a dielectric material such as silicon nitride, so as to reduce a leakage current flowing from each of the two source/drain portions 2 to the fin portion 121, 122 or 123. For example, the bottom region 2B may be formed as bi-layered structure which includes an undoped silicon layer proximate to the underlying portion 110 and a silicon nitride layer distal from the underlying portion 110. In such case, as shown in FIG. 1A, the material for forming the first regions 21 may not formed on the bottom region 2B during formation of the first regions 21. In some other embodiments not shown therein, the bottom region 2B may include a semiconductor material the same as or different from each of the fin portions 121, 122, 123, but are undoped, so that the bottom region 2B may have a higher electrical resistance than each of the fin portions 121, 122, 123. For example, the bottom region 2B may be made of an undoped single crystalline silicon, and thus the bottom region 2B may be also beneficial to the quality of a corresponding one of the source/drain portions 2 to be epitaxially formed thereon. In such case, the material for forming the first regions 21 may be formed on the bottom region 2B during formation of the first regions 21.

In each of the transistors 11, 12, 13, as shown in FIGS. 1A and 1C, the gate dielectric layer 41 is formed around the three channel portions 3. In some embodiments, the gate dielectric layer 41 includes silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, etc.), other suitable materials, or combinations thereof. Other dielectric materials suitable for the gate dielectric layer 41 are within the contemplated scope of the present disclosure. In some embodiments, the gate dielectric layer 41 has a thickness ranging from about 10 Å to about 25 Å.

In each of the transistors 11, 12, 13, as shown in FIGS. 1A to 1C, the gate electrode 42 is elongated in the Y direction, and is formed on the gate dielectric layer 41, such that the gate electrode 42 is separated from the three channel portions 3 by the gate dielectric layer 41. In some embodiments, as shown in FIG. 1C, the gate electrode 42 may be configured as a multi-layered structure which includes a work-function portion 421 which is provided for adjusting threshold voltage of an n-FET or a p-FET, and an electrically conductive filling portion 422 which has a low resistance and which is provided for reducing overall electrical resistance of the gate electrode 42. In some embodiments, the work-function portion 421 is formed on the gate dielectric layer 41, and the electrically conductive filling portion 422 is formed on the work-function portion 421.

In some embodiments, the work-function portion 421 of the gate electrode 42 for forming an n-FET may be different from that for forming a p-FET so as to permit the n-FET and the p-FET to have different threshold voltages. In some embodiments, the work-function portion 421 may be made of an n-band edge work-function material. In some embodiments, the n-band edge work-function material includes titanium aluminum, titanium aluminum carbide, titanium carbide, titanium silicon nitride, aluminum, tantalum aluminum carbide, tantalum aluminum silicide, tantalum silicon carbide, tantalum silicide, hafnium carbide, tantalum, titanium nitride, aluminum carbide, zirconium, silver, or combinations thereof. In some embodiments, the work-function portion 421 may be made of a p-band edge work-function material. In some embodiments, the p-band edge work-function material includes titanium nitride, tungsten, tungsten carbon nitride, ruthenium, molybdenum, tantalum nitride, tungsten nitride, tantalum silicon nitride, chromium, osmium, rhenium, rhodium, iridium, platinum, or combinations thereof. In some embodiments, the work-function portion 421 may be made of a mid-gap work function material which has a Fermi-energy level that is close to halfway between energy levels of a conduction band edge and a valance band edge of each of the three channel portions 3. When each of the three channel portions 3 is made of silicon, the work-function portion 421 may include titanium nitride, tantalum nitride, titanium aluminide, titanium aluminum carbide, titanium aluminum carbon nitride, or combinations thereof. Other materials suitable for forming the work-function portion 421 to adjust the threshold voltages are within the contemplated scope of the present disclosure.

In some embodiments, the electrically conductive filling portion 422 includes tungsten (W), cobalt (Co), ruthenium (Ru), iridium (Ir), alloy thereof, or combinations thereof. Other materials suitable for the electrically conductive filling portion 422 are within the contemplated scope of the present disclosure.

Referring to FIG. 1B, in some embodiments, the gate electrode 42 of each of the transistors 11, 12, 13 has a width K1, K2 or K3 in the X direction. Each of the widths K1, K2 and K3 may range from about 8 nm to about 30 nm. The widths K1, K2, K3 may be the same as or different from each other. In the case that the widths K1, K2, K3 are the same, the length L2 may be smaller each of the lengths L1 and L3. Furthermore, the length L3 is substantially equal to the length L1.

In each of the transistors 11, 12, 13, as shown in FIG. 1A, each pair of the inner spacers 5 are respectively disposed beneath the two channel ends 3E of a corresponding one of the three channel portions 3 so as to separate the gate electrode 42 from the two source/drain portions 2. In some embodiments, each of the inner spacers 5 includes a low-k dielectric material such as silicon oxide, silicon nitride, silicon oxynitride, silicon carbonitride, silicon oxycarbide, silicon oxycarbonitride, silicon carbide, or combinations thereof. Other low-k dielectric materials suitable for the inner spacers 5 are within the contemplated scope of the present disclosure.

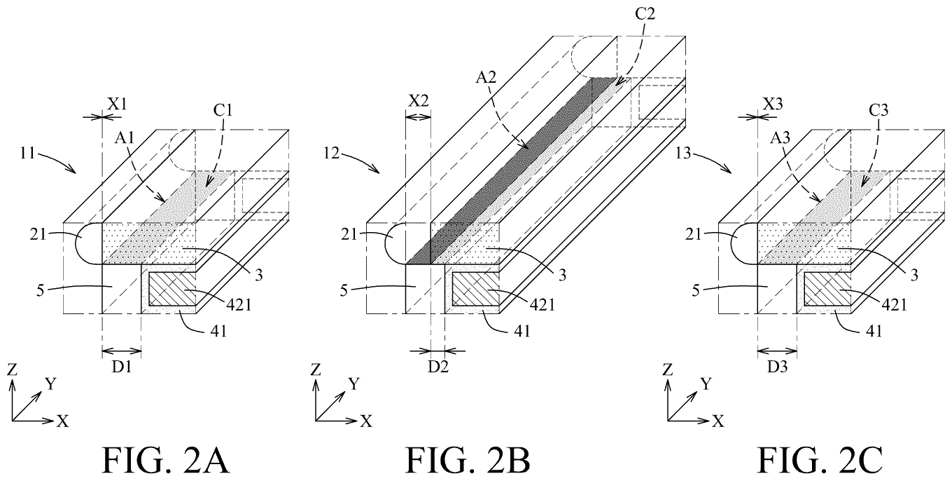

FIGS. 2A, 2B and 2C are fragmentary enlarged perspective views respectively illustrating details regarding an area Z1 of the first transistor 11, an area Z2 of the second transistor 12 and an area Z3 of the third transistor 13 in FIG. 1A in accordance with some embodiments. In FIGS. 2A to 2C, an uppermost one of the three channel portions 3 for each of the transistors 11, 12, 13 is partially shown. In addition, for each of the transistors 11, 12, 13, an uppermost one of the first regions 21 in a left one of the two source/drain portions 2 and a left inner spacer in an uppermost one pair of the inner spacers 5 are shown.

Referring to FIGS. 2A to 2C, the inner spacer 5 and the channel portion 3 define therebetween a contact surface C1 for the first transistor 11, a contact surface C2 for the second transistor 12 and a contact surface C3 for the third transistor 13. Each of the contact surfaces C1, C2 or C3 has a dimension D1, D2 or D3 in the X direction. In some embodiments, the dimension D2 is smaller than each of the dimension D3 and the dimension D1. In some embodiments, the dimension D3 is substantially equal to the dimension D1.

Referring to FIG. 2A to 2C, the first region 21 overlaps the inner spacer 5 in the Z direction to define an overlap area which is denoted by A1 for the first transistor 11, A2 for the second transistor 12, and A3 for the third transistor 13. In some embodiments, the overlap area A2 is greater than each of the overlap area A3 and the overlap area A1. In some embodiments, as shown in FIGS. 2A and 2C, each of the overlap area A1 and the overlap area A3 is close to about zero.

Referring to FIG. 2A to 2C, the distance between the first region 21 and the gate electrode 42 is positively correlated to the dimension of the contact surface in the X direction between the inner spacer 5 and the channel portion 3, and is negatively correlated to the overlap area between the first region 21 and the inner spacer 5 in the Z direction. That is, the distance between the first region 21 and the gate electrode 42 in the second transistor 12 is smaller than the distance between the first region 21 and the gate electrode 42 in each of the first and third transistors 11, 13. As such, in comparison with each of the first and third transistors 11, 13, the second transistor 12 may have a better device performance (e.g., higher saturation drain current (Ids) in the channel, higher speed, higher frequency), whereas in comparison with the second transistor 12, each of the transistors 11, 13 may have a lower leakage current.

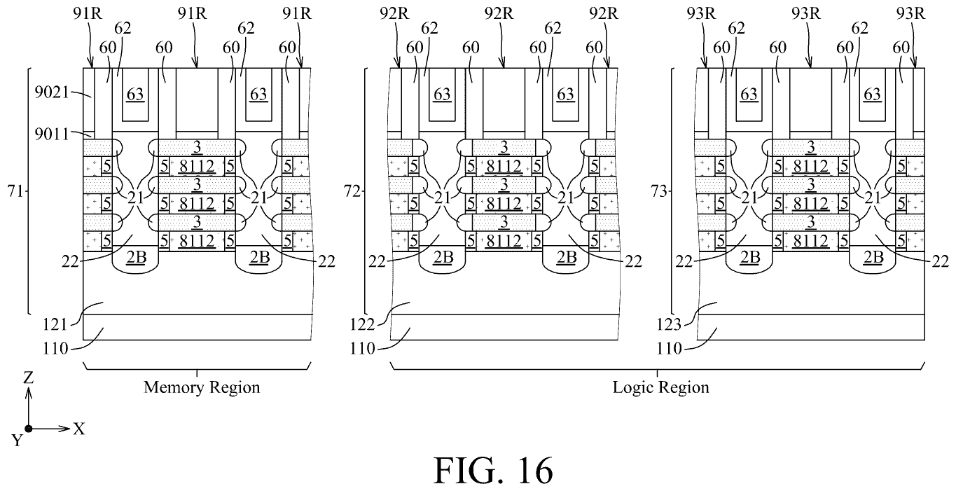

In some embodiments, referring back to FIG. 1A, each of the transistors 11, 12, 13 may further include (i) two gate spacers 61 respectively formed at two opposite sides of the gate electrode 42 in the X direction, (ii) two contact etch stop layer (CESL) portions 62 (see also FIG. 16) formed to respectively cover the two source/drain portions 2, (iii) two inter-layer dielectric (ILD) portions 63 (see FIG. 16) respectively formed on the CESL portions 62, (iv) two contact portions 64 each of which is formed in a corresponding one of the ILD portions 63 and a corresponding one of the CESL portions 62 so as to permit the two contact portions 64 to be electrically connected to the two source/drain portions 2, respectively, and (v) two metal silicide portions 65 each of which is formed between one of the two source/drain portions 2 and a corresponding one of the contact portions 64 so as to reduce the contact resistance (Rcsd) between the one of the two source/drain portions 2 and the corresponding one of the contact portions 64. Details regarding the materials of the elements 61, 62, 63, 64, 65 will be described hereinafter.

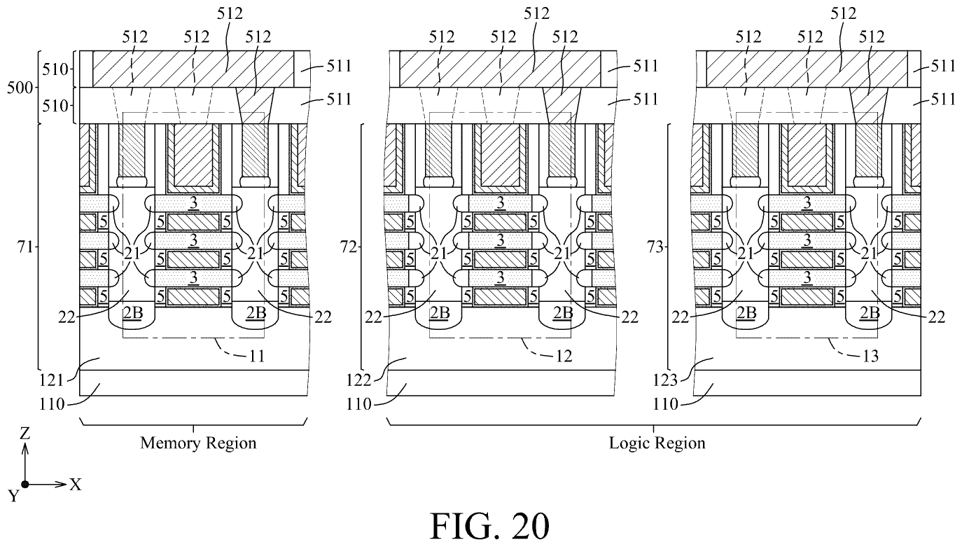

In some alternative embodiments, the semiconductor structure 1 may further include additional features, and/or some features present in the semiconductor structure 1 may be modified, replaced, or eliminated without departure from the spirit and scope of the present disclosure. For example, the semiconductor structure 1 may further include an interconnect structure 500 (see FIG. 20) formed on the transistors 11, 12, 13 so as to permit each of the transistors 11, 12, 13 to be controlled by an external circuit. The details of the interconnect structure 500 will be described hereinafter.

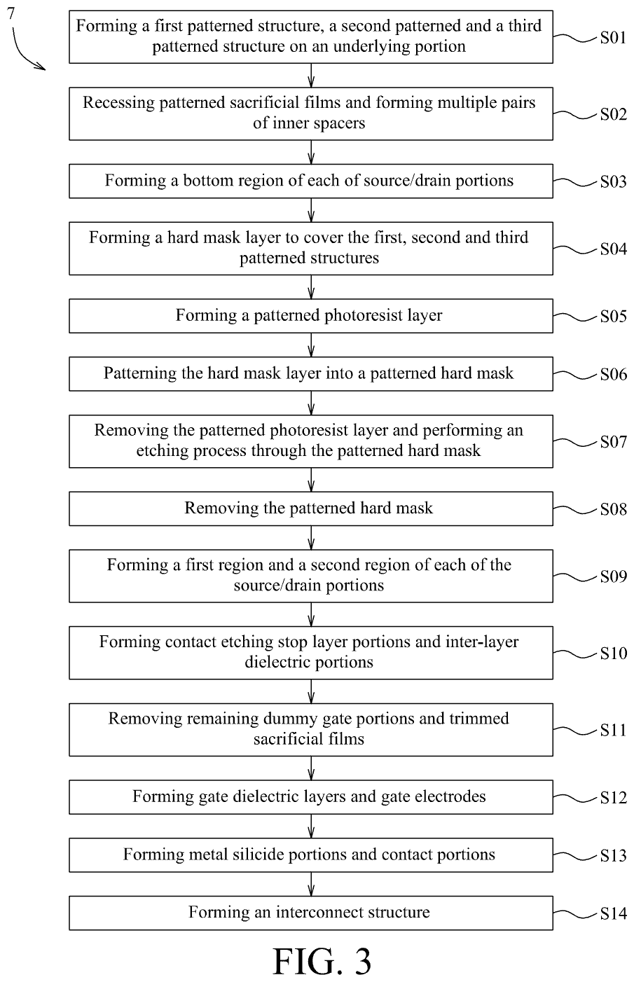

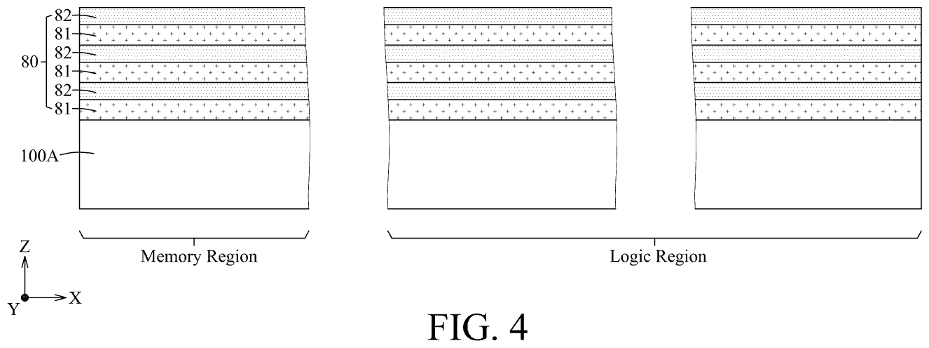

FIG. 3 is a flow diagram illustrating a method 7 for manufacturing a semiconductor structure (for example, but not limited to, the semiconductor structure 1 including the transistors 11, 12, 13 as shown in FIG. 1A) in accordance with some embodiments. The method 7 may include steps S01 to S14. FIGS. 4 to 20 illustrate schematic views of intermediate stages of the method 7 in accordance with some embodiments. Similar numerals from the above-mentioned embodiments have been used where appropriate, with some construction differences being indicated with different numerals. It should be noted that the number of each of the transistors 11, 12, 13 may vary according to practical requirements.

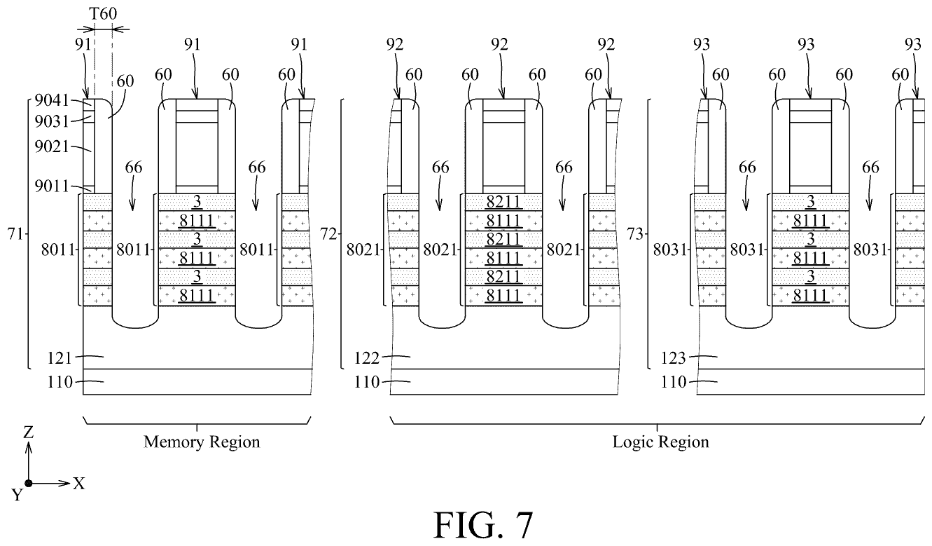

Referring to FIG. 3 and the example illustrated in FIGS. 4 to 7, the method 7 begins at step S01, where a first patterned structure 71 (see FIG. 7) is formed on a memory region of the underlying portion 110, and a second patterned structure 72 (see FIG. 7) and a third patterned structure 73 (see FIG. 7) are both formed on a logic region of the underlying portion 110. The memory region and the logic region in the underlying portion 110 or in a starting substrate 100A (to be described below) are respectively in positions corresponding to the memory region and the logic region of the substrate 100 shown in FIG. 1A. The underlying portion 110 may serve as a base structure for forming the patterned structures 71, 72, 73 thereon. In some embodiments, step S01 may include multiple sub-steps which are described in the following with reference to FIGS. 4 to 7.

In the sub-step shown in FIG. 4, a stack 80 of three sacrificial layers 81 and three channel layers 82 is formed on the memory region and the logic region of a starting substrate 100A by chemical vapor deposition (CVD), atomic layer deposition (ALD), an epitaxial growth process (such as molecular-beam epitaxy (MBE), selective area epitaxy (SAE), etc.), or other suitable deposition techniques. The starting substrate 100A will be patterned into the substrate 100 (see FIG. 1A) in a subsequent step, and thus, the starting substrate 100A includes the material(s) of the substrate 100. The sacrificial layers 81 are disposed to alternate with the channel layers 82 in the Z direction. The channel layers 82 are used for forming the channel portions 3 of each of the transistors 11, 12, 13, and thus each of the channel layers 82 includes the semiconductor material for forming the channel portions 3 of each of the transistors 11, 12, 13. Each of the sacrificial layers 81 is made of a material different from the semiconductor material of the channel layers 82, such that each of the sacrificial layers 81 may be selectively removed with the channel layers 82 being substantially intact due to different etching selectivities. In some embodiments, each of the channel layers 82 is made of silicon, and each of the sacrificial layers 81 is made of silicon germanium. In some embodiments, each of the channel layers 81 has a thickness ranging from about 3 nm to about 8 nm. In some embodiments, each of the sacrificial layers 82 has a thickness ranging from about 5 nm to about 12 nm.

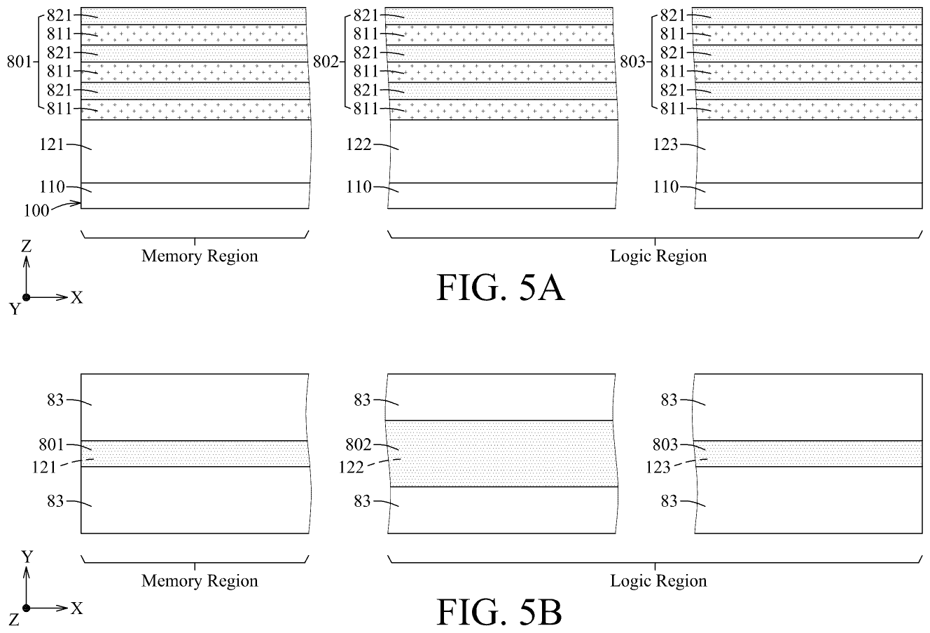

Referring to FIG. 5A which is a schematic sectional view subsequent to FIG. 4, the stack 80 and the starting substrate 100A (see FIG. 4) are patterned, and then an isolation portion 83 are formed. FIG. 5B is a schematic top view of the structure of FIG. 5A in accordance with some embodiments.

The starting substrate 100A is patterned into the underlying portion 110 (see also FIG. 1A) and the fin portions 121, 122, 123 disposed on the underlying portion 110 by suitable processes including lithography and etching steps. The stack 80 is patterned into a first fin stack 801 formed on the first fin portion 121, a second fin stack 802 formed on the second fin portion 122, and a third fin stack 803 formed on the third fin portion 123. Each of the film stacks 801, 802, 803 includes three sacrificial films 811 which are respectively obtained from the sacrificial layers 81 and three channel films 821 which are respectively obtained from the channel layers 82.

The isolation portion 83 is formed on the underlying portion 110 so as to separate the fin portions 121, 122, 123 from an adjacent fin portion (not shown) using suitable processes including a deposition technique (for example, but not limited to, CVD or ALD) and an etching technique (for example, but not limited to, dry etching, wet etching, or a combination thereof). In some embodiments, the fin portions 121, 122, 123 may be also separated from each other by the isolation portion 83. In some embodiments, the isolation portion 83 may each be a shallow trench isolation (STI), a deep trench isolation (DTI), or other suitable structures. In some embodiments, the isolation portion 83 may include silicon oxide, silicon nitride, silicon oxynitride, or combinations thereof. Other insulating materials suitable for the isolation portion 83 are within the contemplated scope of the present disclosure.

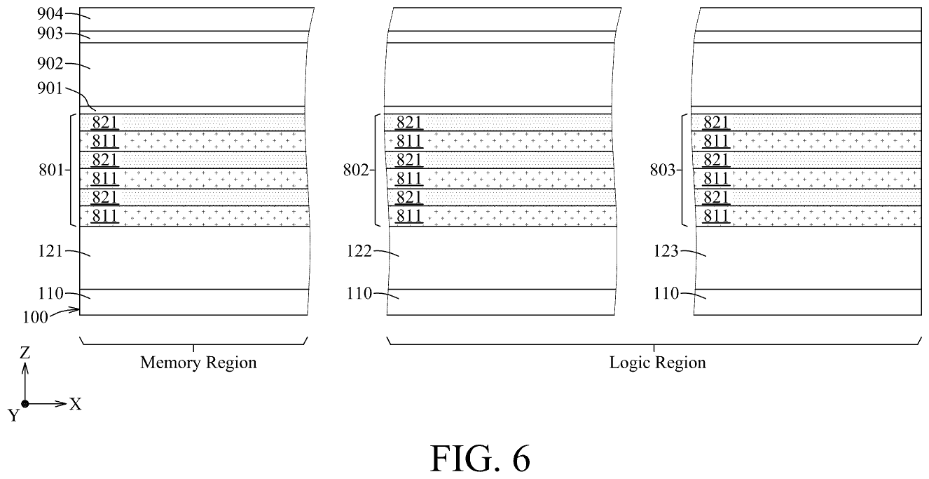

Referring to FIG. 6 which is a schematic sectional view subsequent to FIG. 5A, a dummy gate dielectric layer 901 and a dummy gate electrode layer 902 are sequentially formed on the structure shown in FIG. 5A by CVD, ALD, physical vapor deposition (PVD), or other suitable deposition techniques, followed by a planarization process (e.g., chemical mechanical polishing) to obtain a planar upper surface of the dummy gate electrode layer 902. Afterwards, a polish stop layer 903 and a cap layer 904 are sequentially formed on the dummy gate electrode layer 902 by CVD, ALD, PVD, or other suitable deposition techniques.

In some embodiments, the dummy gate dielectric layer 901 may include silicon oxide, silicon nitride, silicon oxynitride, high dielectric constant (k) materials, other suitable dielectric materials, or combinations thereof. The dummy gate electrode layer 902 may include polycrystalline silicon, single crystalline silicon, amorphous silicon, or combinations thereof. The polish stop layer 903 may include silicon nitride, silicon oxide, silicon oxynitride, or combinations thereof. The cap layer 904 may include silicon nitride, silicon oxide, silicon oxynitride, or combinations thereof. It is noted that the material of the cap layer 904 is different from the material of the polish stop layer 903. For example, the polish stop layer 903 is made of silicon nitride, and the cap layer 904 is made of silicon oxide.

Referring to FIG. 7 which is a schematic sectional view subsequent to FIG. 6, the stack of the layers 901, 902, 903, 904 (see FIG. 6) are patterned to form three first dummy gate portions 91 on the first fin stack 801 (see FIG. 6), three second dummy gate portions 92 on the second fin stack 802 (see FIG. 6) and three third dummy gate portions 93 on the third fin stack 803 (see FIG. 6). Then, each of the dummy gate portions 91, 92, 93 are formed with two gate spacers 60 opposite to each other in the X direction. Afterwards, each of the fin stacks 801, 802, 803 (see FIG. 6) is patterned to form two source/drain recesses 66 spaced apart from each other in the X direction. Accordingly, the patterned structures 71, 72, 73 are thus obtained.

In detail, in some embodiments, the patterning of the stack of the layers 901, 902, 903, 904 is performed using a photolithography technique and/or an etching technique (for example, but not limited to, dry etching, wet etching, or a combination thereof). The dummy gate portions 91, 92 or 93, which are formed on a corresponding one of the first, second and third fin stacks 801, 802, 803 (see FIG. 6), are spaced apart from each other in the X direction, and are each elongated in the Y direction. Each of the dummy gate portions 91, 92, 93 includes a dummy gate dielectric film 9011, a dummy gate electrode part 9021, a polish stop film 9031 and a cap film 9041 which are respectively obtained from the dummy gate dielectric layer 901, the dummy gate electrode layer 902, the polish stop layer 903 and the cap layer 904.

Then, each of the dummy gate portions 91, 92, 93 are formed with the two gate spacers 60 by CVD, ALD, PVD, or other suitable deposition techniques, followed by an isotropic etching process to expose the dummy gate portions 91, 92, 93 and the fin stacks 801, 802, 803 (see FIG. 6). The gate spacers 60 may be made of a dielectric material which includes a nitride-based material, such as silicon nitride, silicon oxynitride, silicon carbon nitride, silicon oxycarbonnitride, but is not limited thereto. Other dielectric materials suitable for the gate spacers 60 are within the contemplated scope of the present disclosure. In some embodiments, each of the gate spacers 60 may have a thickness T60 in the X direction ranging from about 6 nm to about 12 nm.

Afterwards, the two source/drain recesses 66 are formed by an etching technique (for example, but not limited to, dry etching, wet etching, or a combination thereof), such that each of the fin stacks 801, 802, 803 (see FIG. 6) is patterned into three film stacks 8011, 8021 or 8031 disposed to alternate with the two source/drain recesses 66 in the X direction. In some embodiments, each of the fin portions 121, 122, 123 is etched during formation of the two source/drain recesses 66 such that a bottommost point of each of the two source/drain recesses 66 is at a level lower than a bottommost surface of each of the film stacks 8011, 8021, 8031.

In each of the first and third patterned structures 71, 73, the patterned channel films at a middle one of the three film stacks 8011 or 8031 serve as the channel portions 3 of the transistor 11 or 13 (see FIG. 1A), and the patterned sacrificial films are denoted by the numeral 8111. In the patterned structure 72, the patterned channel films are denoted by the numeral 8211, and the patterned sacrificial films are denoted by the numeral 8111. In some embodiments, after formation of the source/drain recesses 66, the channel portions 3 in the first and third patterned structures 71, 73 and the patterned channel films 8211 in the second patterned structure 72 have the same length in the X direction.

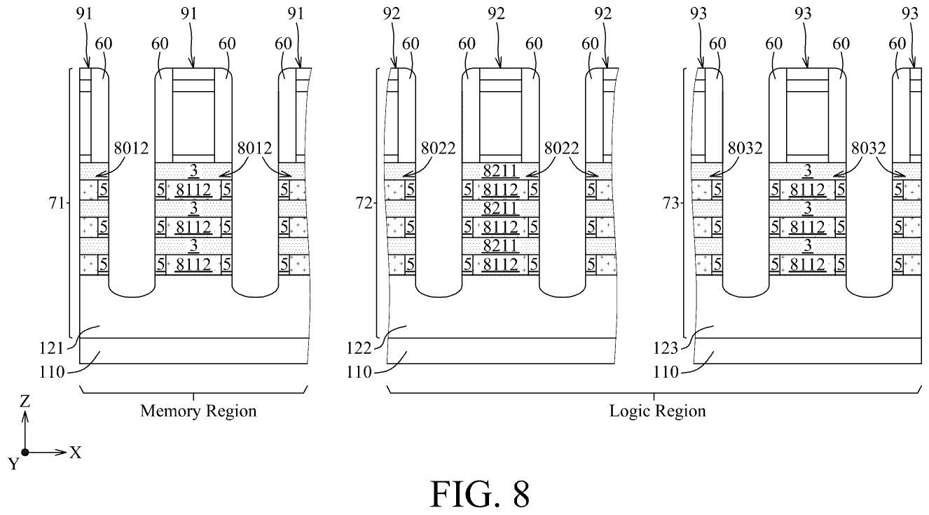

Referring to FIG. 3 and the example illustrated in FIG. 8, the method 7 proceeds to step S02, where for each of the patterned structures 71, 72, 73, the patterned sacrificial films 8111 (see FIG. 7) are recessed, and then multiple pairs of the inner spacers 5 are formed. FIG. 8 is a schematic sectional view similar to FIG. 7, but illustrating the structure after step S02. In some embodiments, step S02 may be performed as follow.

First, the patterned sacrificial films 8111 (see FIG. 7) in each of the film stacks 8011, 8021 or 8031 are laterally trimmed by an etching process, and the trimmed sacrificial films are denoted by the numeral 8112. Then, each pair of the inner spacers 5 are formed at two opposite sides of a corresponding one of the trimmed sacrificial films 8112 by depositing a low-k dielectric material for forming the inner spacers 5 using CVD, ALD, PVD, or other suitable deposition techniques, followed by an isotropic etching process to remove excess portions of the low-k dielectric material. After step S02, the film stacks obtained from the film stacks 8011, 8021, 8031 are denoted by the numeral 8012, 8022, 8032.

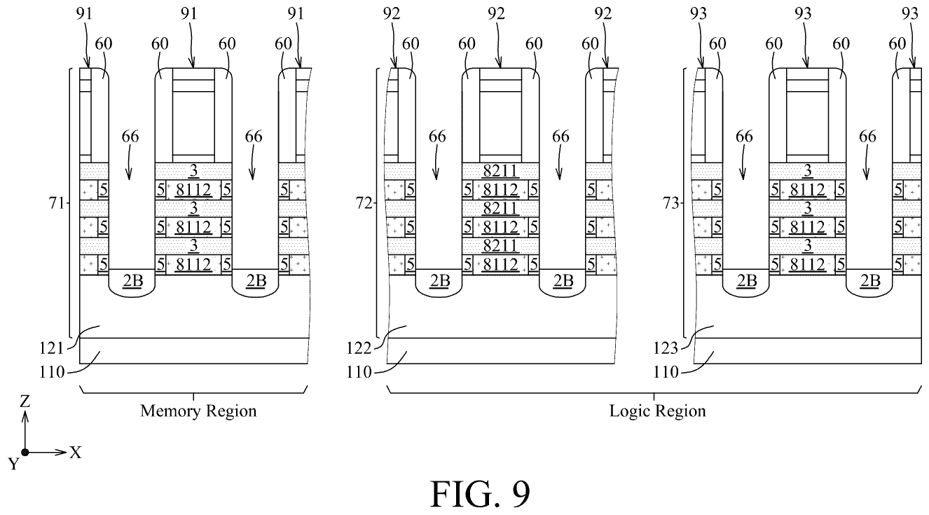

Referring to FIG. 3 and the example illustrated in FIG. 9, the method 7 proceeds to step S03, where for each of the patterned structures 71, 72, 73, the bottom region 2B of each of the source/drain portions 2 (see also FIG. 1A) is formed on the fin portion 121, 122 or 123 at a bottom region of a corresponding one of the source/drain recesses 66 by an epitaxial growth process including CVD, molecular-beam epitaxy (MBE), an epitaxial deposition/partial etch process, such as a cyclic deposition-etch (CDE) process, and/or a selective epitaxial growth (SEG) process, but is not limited thereto. Other suitable processes for forming the bottom region 2B are within the contemplated scope of the present disclosure. FIG. 9 is a schematic sectional view similar to FIG. 8, but illustrating the structure after step S03.

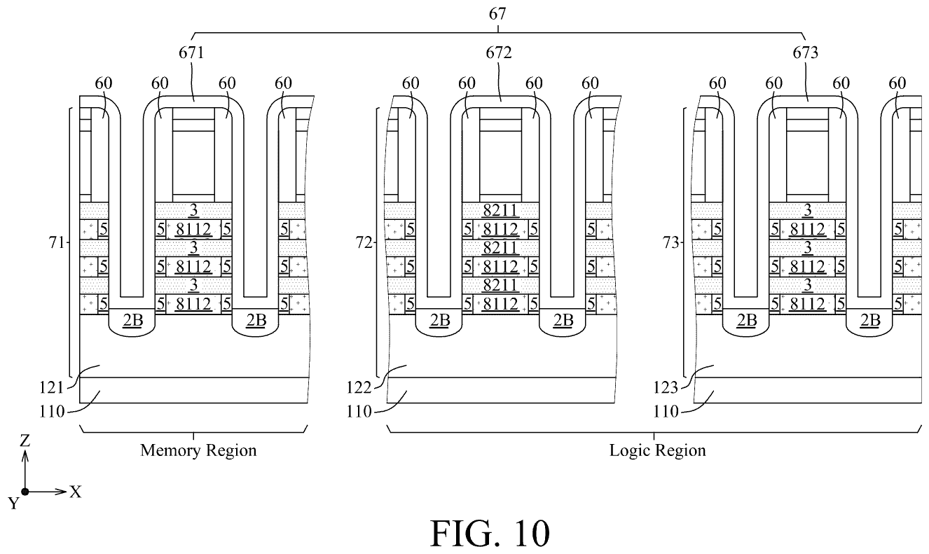

Referring to FIG. 3 and the example illustrated in FIG. 10, the method 7 proceeds to step S04, where a hard mask layer 67 is formed to cover the patterned structures 71, 72, 73 by CVD, ALD, PVD, or other suitable deposition techniques. FIG. 10 is a schematic sectional view similar to FIG. 9, but illustrating the structure after step S04.

In some embodiments, the hard mask layer 67 may include an oxide, a nitride, a carbide, an oxynitride, an oxycarbide, a carbonitride, an oxycarbonitride, or combinations thereof. For example, the hard mask layer 67 may be made of silicon oxide, aluminum oxide, hafnium oxide, zirconium oxide, silicon nitride, aluminum nitride, titanium nitride, silicon carbide, silicon oxycarbide, silicon oxynitride, silicon carbonitride, silicon oxycarbonitride, or combinations thereof. The hard mask layer 67 has a first region 671, a second region 672 and a third region 673 respectively formed on the first patterned structure 71, the second patterned structure 72 and the third patterned structure 73.

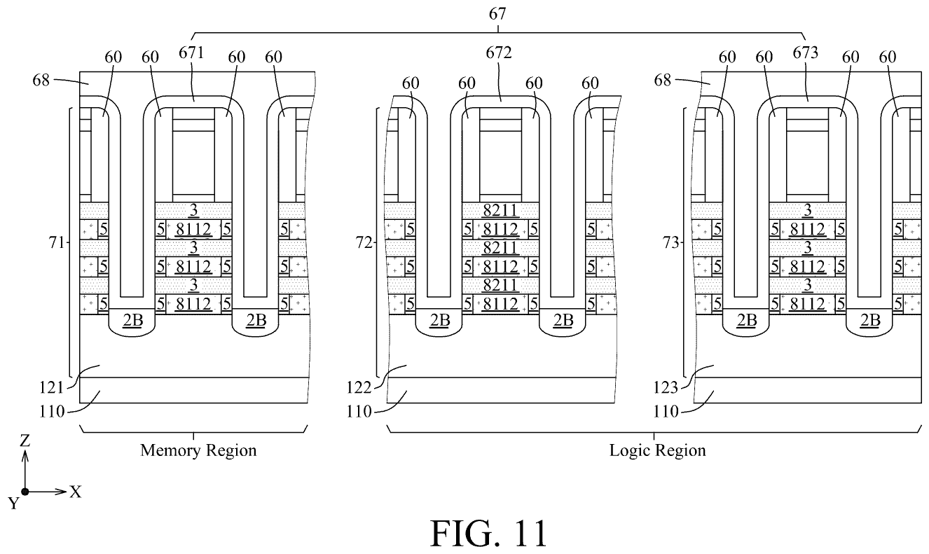

Referring to FIG. 3 and the example illustrated in FIG. 11, the method 7 proceeds to step S05, where a patterned photoresist layer 68 is formed to cover the regions 671, 673 of the hard mask layer 67 to expose the second region 672 of the hard mask layer 67. FIG. 11 is a schematic sectional view similar to FIG. 10, but illustrating the structure after step S05.

In some embodiments, formation of the patterned photoresist layer 68 may be performed by spin-coating a photoresist layer (not shown) on the regions 671, 672, 673 of the hard mask layer 67, and patterning the photoresist layer to expose the region 672 of the hard mask layer 67 by a lithography technique including exposure and developing processes. Other suitable processes for forming the patterned photoresist layer 68 are within the contemplated scope of the present disclosure.

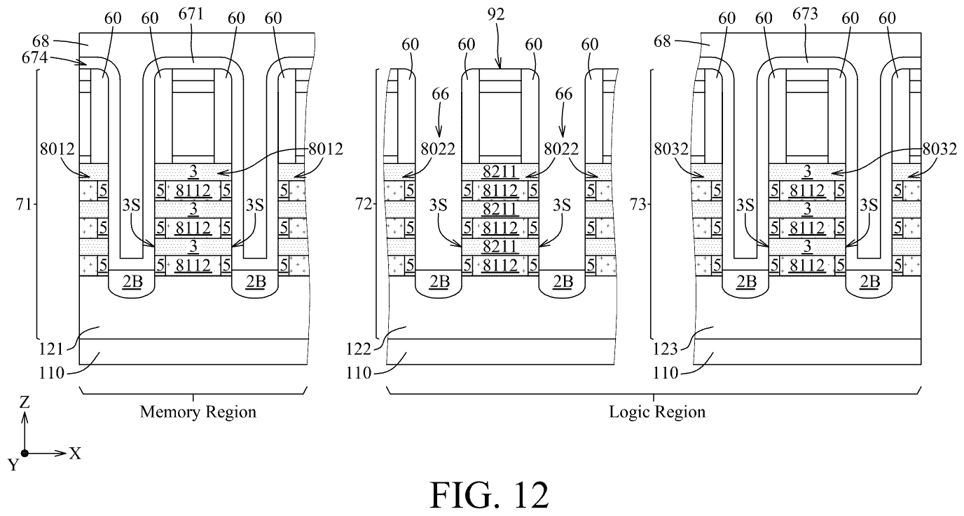

Referring to FIG. 3 and the example illustrated in FIG. 12, the method 7 proceeds to step S06, where the second region 672 of the hard mask layer 67 (see FIG. 11) is removed by a wet etching process and/or a dry etching process, and thus the hard mask layer 67 is formed into a patterned hard mask 674 which includes the first and third regions 671, 673 respectively covering the first and third patterned structures 71, 73. FIG. 12 is a schematic sectional view similar to FIG. 11, but illustrating the structure after step S06.

In some embodiments, the wet etching process used for the removal of the second region 672 of the hard mask layer 67 may utilize one or more wet etchant solutions which have a relatively higher etching selectivity (or higher etching rate) over the material of the hard mask layer 67 so that the second patterned structure 72 located beneath the second region 672 of the hard mask layer 67 is substantially not removed or damaged.

Each of the patterned channel films 8211 in each of the film stacks 8012, 8022, 8032 has two end surfaces 3S opposite to each other in the X direction. After step S06, the two end surfaces 3S of each of the patterned channel films 8211 in each of the film stacks 8022 are exposed from the second patterned structure 72 respectively through the source/drain recesses 66, and the two end surfaces 3S of each of the patterned channel films 8211 in each of the film stacks 8012, 8032 are covered by the patterned hard mask 674.

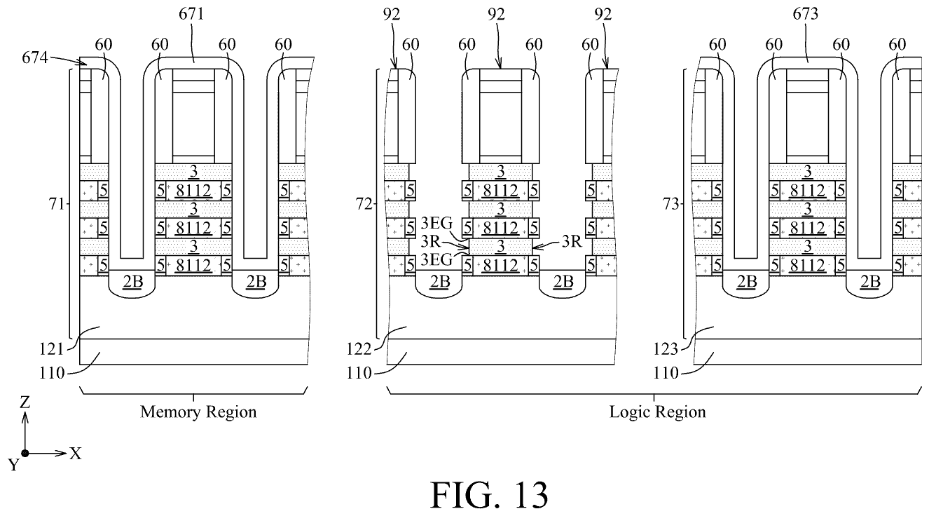

Referring to FIG. 3 and the example illustrated in FIG. 13, the method 7 proceeds to step S07, where the patterned photoresist layer 68 (see FIG. 12) is removed by a stripping process, and then the patterned structures 71, 72, 73 are subjected to an etching process. FIG. 13 is a schematic sectional view similar to FIG. 12, but illustrating the structure after step S07.

The etching process is performed through the patterned hard mask 674 to reduce a minimum distance between the two end surfaces 3S of each of the patterned channel films 8211 (see FIG. 12) in the second patterned structure 72. To be specific, in step S07, the patterned channel films 8211 in the patterned structure 72 are selectively recessed while keeping the three dummy gate portions 92, the gate spacers 60 and the inner spacers 5 in the second patterned structure 72 intact. After step S07, the patterned channel films 8211 at a middle one of the film stacks 8022 are formed into the channel portions 3 of the second transistor 12 (see FIG. 1A) each having two recessed end surfaces 3R opposite to each other in the X direction. Each of the two recessed end surfaces 3R of the second transistor 12 may be a planar surface, a concave surface, or a convex surface. Each of the recessed end surfaces 3R has two edges 3EG opposite to each other in the Z direction. It is noted that the etching process is performed to prevent the trimmed sacrificial films 8112 and the dummy gate portions 92 from being exposed from the recessed end surfaces 3R of the channel portions 3 in the second patterned structure 72. Furthermore, it is noted that according to the material of the bottom region 2B of each of the source/drain portions 2 in the second patterned structure 72, the bottom region 2B may be or may not be etched during the etching process. For example, in some embodiments, as shown in FIGS. 12 and 13, when the bottom region 2B is formed as a bi-layered structure, since it is the silicon nitride layer of the bottom region 2B that is exposed from the patterned hard mask 674, the bottom region 2B may not be etched during the etching process. In some other embodiments, when the bottom region 2B is made of an undoped single crystalline silicon, the bottom region 2B that is exposed from the patterned hard mask 674 may be etched to have a reduced thickness in the Z direction during the etching process.

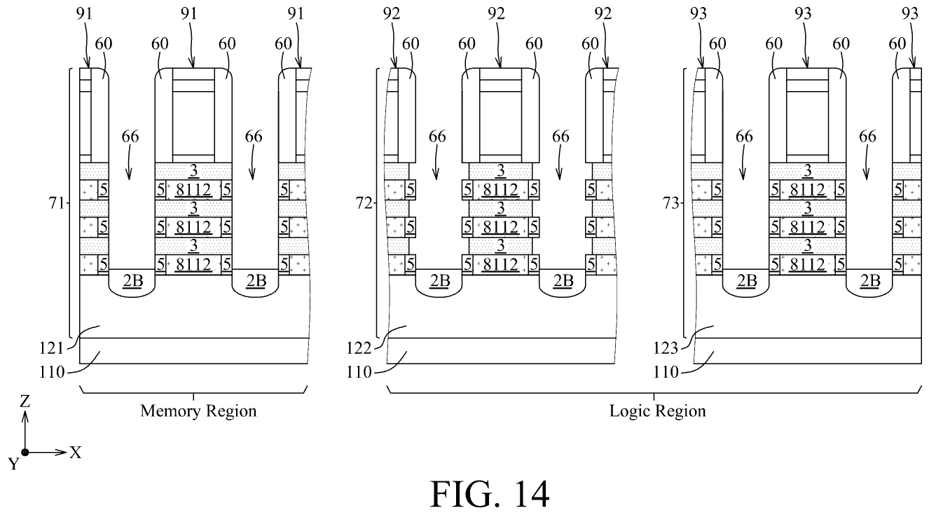

Referring to FIG. 3 and the example illustrated in FIG. 14, the method 7 proceeds to step S08, where the patterned hard mask 674 (see FIG. 13) is removed in a manner similar to the removal of the second region 672 of the hard mask layer 67 as described above in step S06, so that the first and third patterned structures 71, 73 located beneath the patterned hard mask 674 is substantially not removed or damaged. FIG. 14 is a schematic sectional view similar to FIG. 13, but illustrating the structure after step S08.

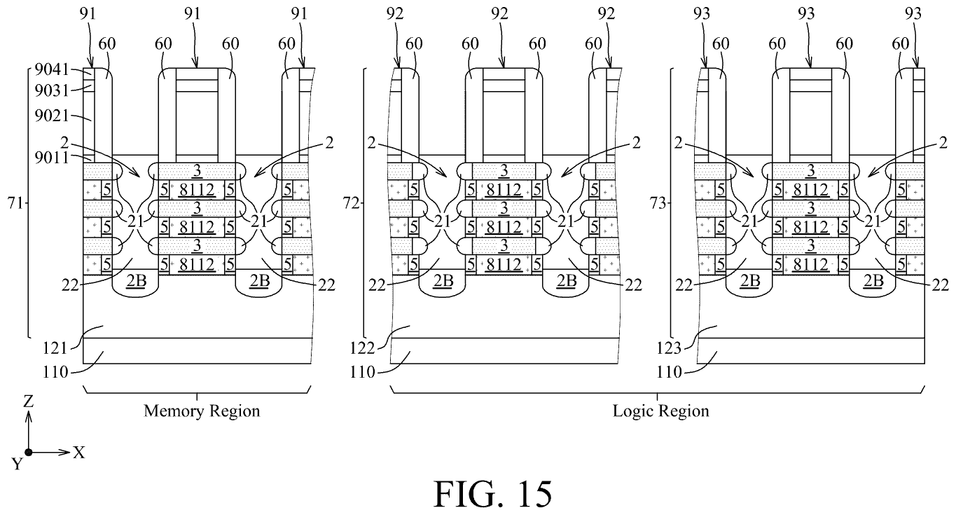

Referring to FIG. 3 and the example illustrated in FIG. 15, the method 7 proceeds to step S09, where for each of the patterned structures 71, 72, 73, the two source/drain portions 2 of a corresponding one of the transistors 11, 12, 13 (see FIG. 1A) are formed to respectively fill the source/drain recesses 66 (see FIG. 14) by an epitaxial growth process. FIG. 15 is a schematic sectional view similar to FIG. 14, but illustrating the structure after step S09.

Since each of the transistors 11, 12, 13 may be an n-FET or a p-FET, based on the types of the transistors 11, 12, 13, formation of the two source/drain portions 2 in the first patterned structure 71, formation of the two source/drain portions 2 in the second patterned structure 72, and formation of the two source/drain portions 2 in the third patterned structure 73 may be performed separately or performed at the same time. In general, the source/drain portions 2 having the same conductivity type (n-type or p-type) may be formed at the same time.

In some embodiments, in each of the patterned structures 71, 72, 73, formation of each of the two source/drain portions 2 may include forming the first regions 21 respectively in contact with the channel portions 3 which are exposed from a corresponding one of the source/drain recesses 66 (see FIG. 14), and forming the second region 22 to fill the corresponding one of the source/drain recesses 66. It is worth noting that although each of the channel portions 3 in the first and third patterned structures 71, 73 has a relatively smaller width W1 or W3 in the Y direction (see also FIG. 1B), the channel portions 3 in the first and third patterned structures 71, 73 are not recessed in step S07, and thus the first regions 21 initially grown from the channel portions 3 in the first and third patterned structures 71, 73 may have a better epitaxial quality due to less spatial interference during the epitaxial growth of the first regions 21. On the other hand, the channel portions 3 in the second patterned structure 72 have a relatively greater width W2 in the Y direction (see also FIG. 1B), the first regions 21 may be also well grown from the channel portions 3 in the second patterned structure 72.

Referring to FIG. 3 and the example illustrated in FIG. 16, the method 7 proceeds to step S10, where for each of the patterned structures 71, 72, 73, the two CESL portions 62 are formed to respectively cover the two source/drain portions 2 and the two ILD portions 63 are respectively formed on the CESL portions 62. FIG. 16 is a schematic sectional view similar to FIG. 15, but illustrating the structure after step S10.

In some embodiments, the CESL portions 62 may be made of silicon nitride, and the ILD portions 63 may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), spin-on-glass (SOG), or combinations thereof. Other dielectric materials suitable for the CESL portions 62 and the ILD portions 63 are within the contemplated scope of the present disclosure. In some embodiments, step S10 may be performed by sequentially depositing the materials for the CESL portions 62 and the ILD portions 63 using a deposition process followed by a planarization process to expose the dummy gate electrode part 9021 of each of the dummy gate portions 91, 92 or 93 (see FIG. 15). After step S10, each of the remaining dummy gate portions is denoted by the numeral 91R, 92R or 93R, and includes the dummy gate dielectric film 9011 and the dummy gate electrode part 9021.

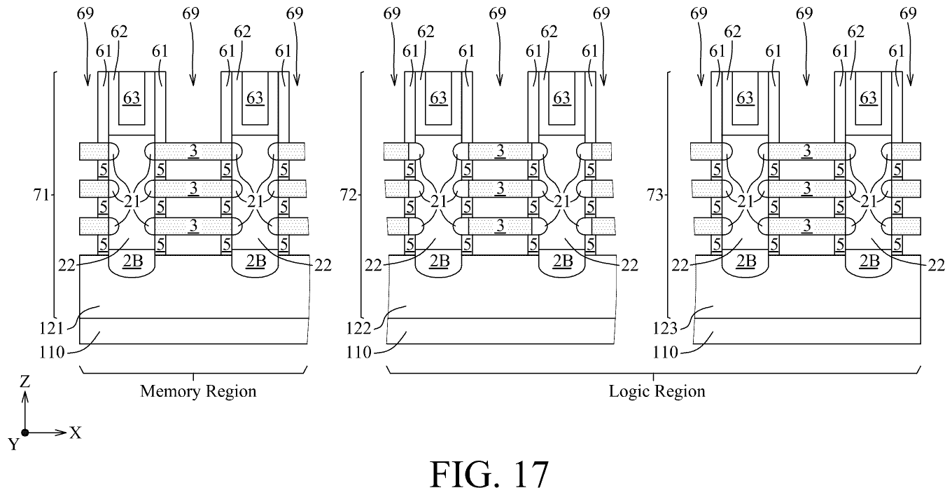

Referring to FIG. 3 and the example illustrated in FIG. 17, the method 7 proceeds to step S11, where in each of the patterned structures 71, 72, 73, the remaining dummy gate portions 91R, 92R or 93R, and the trimmed sacrificial films 8112 are removed to form three cavities 69 using a selective etching process (e.g., a wet etching process) without damaging the channel portions 3. FIG. 17 is a schematic sectional view similar to FIG. 16, but illustrating the structure after step S11. In some embodiments, the thickness of the gate spacers 60 shown in FIG. 16 may be reduced after step S11, and thus the gate spacers after step S11 are denoted by the numeral 61.

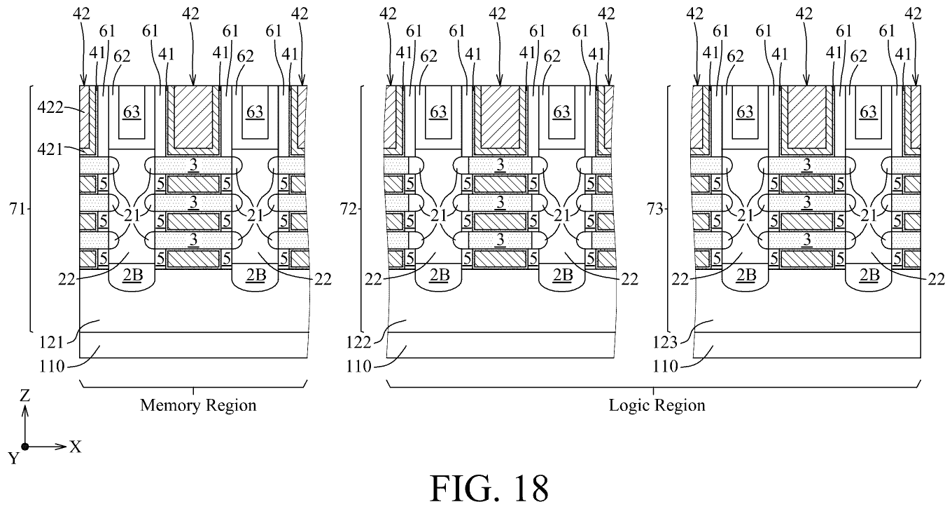

Referring to FIG. 3 and the example illustrated in FIG. 18, the method 7 proceeds to step S12, where for each of the patterned structures 71, 72, 73, three of the gate dielectric layers 41 and three of the gate electrodes 42 are formed. In each of the patterned structures 71, 72, 73, a middle one of the three gate dielectric layers 41 and a middle one of the three gate electrodes 42 respectively serve as the gate dielectric layer 41 and the gate electrode 42 of the transistor 11, 12 or 13 as mentioned above with reference to FIG. 1A. FIG. 18 is a schematic sectional view similar to FIG. 17, but illustrating the structure after step S12.

In some embodiments, formation of the gate dielectric layers 41 and the gate electrodes 42 may include (i) sequentially depositing the materials for the gate dielectric layers 41, and the work-function portion 421 and the electrically conductive filling portion 422 of each of the gate electrodes 42 on the structure shown in FIG. 17 to fill the cavities 69 (see FIG. 17) using CVD, ALD or other suitable deposition techniques, and (ii) performing a planarization process to expose the ILD portions 63.

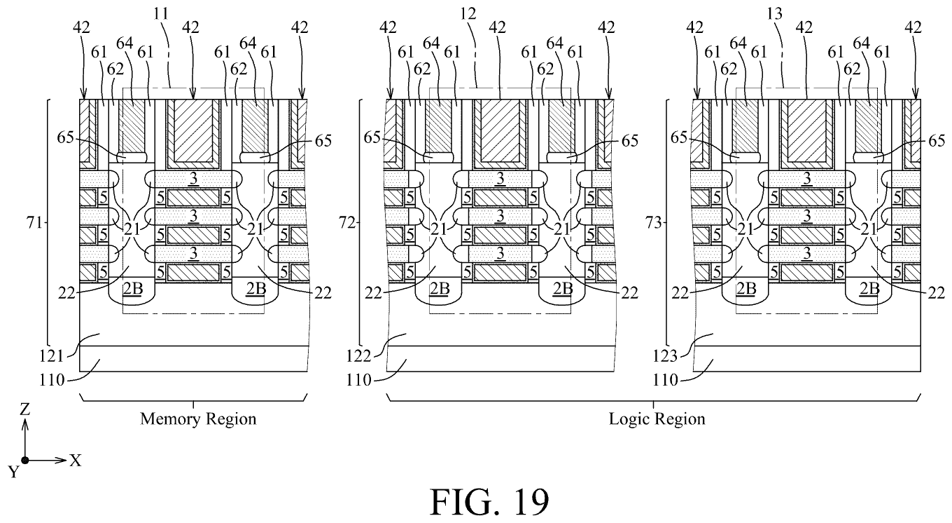

Referring to FIG. 3 and the example illustrated in FIG. 19, the method 7 proceeds to step S13, where for each of the patterned structures 71, 72, 73, the two metal silicide portions 65 and the two contact portions 64 are formed. After step S13, the transistors 11, 12, 13 as described above with reference to FIG. 1A are thus obtained. FIG. 19 is a schematic sectional view similar to FIG. 18, but illustrating the structure after step S13.

In some embodiments, the contact portions 64 may include a conductive material, such as tungsten (W), aluminum (Al), ruthenium (Ru), cobalt (Co), copper (Cu), palladium (Pd), nickel (Ni), platinum (Pt), a low resistivity metal constituent, etc., or combinations thereof. In some embodiments, the metal silicide portions 65 may include titanium (Ti), nickel (Ni), cobalt (Co), ruthenium (Ru), molybdenum (Mo), or combinations thereof. Other suitable materials for the contact portions 64 and the metal silicide portions 65 are within the contemplated scope of the present disclosure. In some embodiments, in order to reduce the contact resistance (Rcsd) between the one of the two source/drain portions 2 and the corresponding one of the contact portions 64, the material(s) of the metal silicide portions 65 in each of the transistors 11, 12, 13 may vary according to the material(s) of the source/drain portions 2 to be connected.

In some embodiments, step S13 may include, in each of the patterned structures 71, 72, 73, (i) forming two openings (not shown) each of which extends through one of the ILD portions 63 and a corresponding one of the CESL portions 62 to expose a corresponding one of the source/drain portions 2 by suitable processes including lithography and etching steps, (ii) forming the metal silicide portions 65 respectively on the source/drain portions 2 using CVD, ALD, PVD, or other suitable deposition techniques, and (iii) forming the contact portions 64 respectively on the metal silicide portions 65 to fill the openings using CVD, ALD, PVD, or other suitable deposition techniques, followed by a planarization process to expose the gate electrodes 42. Other processes suitable for forming the metal silicide portions 65 and the contact portions 64 are within the contemplated scope of the present disclosure.

Referring to FIG. 3 and the example illustrated in FIG. 20, the method 7 proceeds to step S14, where the interconnect structure 500 is formed on the patterned structures 11, 12, 13. FIG. 20 is a schematic sectional view similar to FIG. 19, but illustrating the structure after step S13.

The interconnect structure 500 may include a plurality of interconnect layers 510 each including an inter-metal dielectric (IMD) portion 511 in which a plurality of electrically conductive elements 512 (for example, metal contacts, metal lines and/or metal vias) are formed so as to permit the transistors 11, 12, 13 to be electrically connected to external circuits through the electrically conductive elements 512. In some embodiments, the interconnect structure 500 may be formed by a dual damascene process, a single damascene process, or other suitable back-end-of-line (BEOL) techniques.

In some embodiments, some steps in the method 7 may be modified, replaced, or eliminated without departure from the spirit and scope of the present disclosure.

In summary, in order to reduce current leakage of the first and third transistors and to enhance device performance of the second transistor, the channel length in the first and third transistors is designed to be greater than the channel length in the second transistor. In some embodiments, in order to achieve the difference in channel length, formation of the channel portions of each of the first and third transistors is completed before formation of the channel portions in the second transistor. Furthermore, although the channel portions in each of the first and third transistors have a width in the Y direction less than that of the channel portions in the second transistor, each of the source/drain portions epitaxially grown from the channel portions in each of the first and third transistors may have a good epitaxial quality due to less spatial interference caused by adjacent ones of the inner spacers and/or the gate spacers. In addition, when the first and third transistors with relatively lower current leakage, and the second transistor with relatively higher performance are integrated together in a chip, the performance of the chip can be enhanced, i.e., the chip has relatively longer service lifetime and higher computing speed with greater reliability.

In accordance with some embodiments of the present disclosure, a method for manufacturing a semiconductor structure includes: forming a first patterned structure on a memory region of a base structure and forming a second patterned structure and a third patterned structure on a logic region of the base structure, the logic region being displaced from the memory region, the first patterned structure including a first patterned fin and a first channel portion disposed on and spaced apart from the first patterned fin, the second patterned structure being displaced from the third patterned structure, the second patterned structure including a second patterned fin and a second channel portion disposed on and spaced apart from the second patterned fin, the third patterned structure including a third patterned fin and a third channel portion disposed on and spaced apart from the third patterned fin, each of the first channel portion, the second channel portion and the third channel portion having two exposed end surfaces which are opposite to each other; forming a patterned hard mask covering the first patterned structure and the third patterned structure; and performing an etching process through the patterned hard mask so as to reduce a minimum distance between the two exposed end surfaces of the second channel portion.

In accordance with some embodiments of the present disclosure, the two exposed end surfaces of each of the first channel portion, the second channel portion and the third channel portion are opposite to each other in an X direction.

In accordance with some embodiments of the present disclosure, each of the first channel portion, the second channel portion and the third channel portion is spaced apart from a respective one of the first patterned fin, the second patterned fin and the third patterned fin in a Z direction transverse to the X direction. Each of the first channel portion, the second channel portion and the third channel portion has a width in a Y direction transverse to the X direction and the Z direction. The width of the second channel portion is greater than the width of each of the first channel portion and the third channel portion.

In accordance with some embodiments of the present disclosure, a method for manufacturing a semiconductor structure includes: forming a first patterned structure on a memory region of a base structure and forming a second patterned structure and a third patterned structure on a logic region of the base structure, the logic region being displaced from the memory region, each of the first patterned structure, the second patterned structure and the third patterned structure including a patterned fin, a patterned stack disposed on the patterned fin, the patterned stack including a channel portion and a sacrificial portion disposed beneath the channel portion in a Z direction, the channel portion having two channel ends opposite to each other in an X direction transverse to the Z direction, two inner spacers disposed at two opposite sides of the sacrificial portion in the X direction and disposed beneath the two channel ends of the channel portion in the Z direction, and a dummy gate portion disposed over the patterned stack and elongated in a Y direction transverse to the X direction and the Z direction, the channel portion having two end surfaces which are opposite to each other in the X direction and which are exposed from the dummy gate portion; and performing an etching process to selectively recess the two end surfaces of the channel portion in the second patterned structure without recessing the two end surfaces of the channel portion in the third patterned structure.

In accordance with some embodiments of the present disclosure, a width of the patterned fin in the second patterned structure in the Y direction is greater than each of a width of the patterned fin in the first patterned structure in the Y direction and a width of the patterned fin in the third patterned structure in the Y direction.

In accordance with some embodiments of the present disclosure, before the etching process, the channel portion in the first patterned structure, the channel portion in the second patterned structure, and the channel portion in the third patterned structure have a same length in the X direction.

In accordance with some embodiments of the present disclosure, after the etching process, a contact surface area between each of the two inner spacers and the channel portion in the second patterned structure is smaller than a contact surface area between each of the inner spacers and the channel portion in the third patterned structure.

In accordance with some embodiments of the present disclosure, the method further includes: forming two first source/drain portions respectively at two opposite sides of the dummy gate portion in the first patterned structure such that the channel portion in the first patterned structure extends between the two first source/drain portions; after the etching process, forming two second source/drain portions respectively at two opposite sides of the dummy gate portion in the second patterned structure such that the channel portion in the second patterned structure extends between the two second source/drain portions; and forming two third source/drain portions respectively at two opposite sides of the dummy gate portion in the third patterned structure such that the channel portion in the third patterned structure extends between the two third source/drain portions.

In accordance with some embodiments of the present disclosure, formation of each of the two first source/drain portions, the two second source/drain portions and the two third source/drain portions includes: forming a first region in contact with the channel portion in a corresponding one of the first patterned structure, the second patterned structure and the third patterned structure; and forming a second region to cover the first region such that the second region is separated from the channel portion in the corresponding one of the first patterned structure, the second patterned structure and the third patterned structure. In the first patterned structure, the first region of each of the two first source/drain portions overlaps an adjacent one of the two inner spacers in the Z direction to define a first overlap area. In the second patterned structure, the first region of each of the two second source/drain portions overlaps an adjacent one of the two inner spacers in the Z direction to define a second overlap area. In the third patterned structure, the first region of each of the two third source/drain portions overlaps an adjacent one of the two inner spacers in the Z direction to define a third overlap area. The second overlap area is larger than the third overlap area.

In accordance with some embodiments of the present disclosure, the second overlap area is larger than the first overlap area.

In accordance with some embodiments of the present disclosure, each of the two first source/drain portions, the two second source/drain portions and the two third source/drain portions includes a group IV semiconductor material, and is doped with group V impurities.

In accordance with some embodiments of the present disclosure, each of the two first source/drain portions, the two second source/drain portions and the two third source/drain portions includes a group IV semiconductor material, and is doped with group III impurities.

In accordance with some embodiments of the present disclosure, the dummy gate portion includes a dummy gate and two spacers located at two opposite sides of the dummy gate in the X direction.

In accordance with some embodiments of the present disclosure, the method further includes, after formation of the two first source/drain portions, the two second source/drain portions and the two third source/drain portions, removing the dummy gate and the sacrificial portion in each of the first patterned structure, the second patterned structure and the third patterned structure.

In accordance with some embodiments of the present disclosure, after removing the dummy gate and the sacrificial portion, the method further includes: forming a gate dielectric layer around the channel portion in each of the first patterned structure, the second patterned structure and the third patterned structure; and forming a gate electrode on the gate dielectric layer in each of the first patterned structure, the second patterned structure and the third patterned structure.

In accordance with some embodiments of the present disclosure, a semiconductor structure includes: first transistors disposed on a memory region of a substrate, and a second transistor and a third transistor disposed on a logic region of the substrate. Each of the first transistors, the second transistor and the third transistor includes two source/drain portions spaced apart from each other in an X direction, a channel portion extending between the two source/drain portions in the X direction to terminate at two channel ends, and having a width in a Y direction transverse to the X direction, a gate electrode elongated in the Y direction, and disposed around the channel portion, and two inner spacers disposed beneath the two channel ends of the channel portion so as to separate the gate electrode from the two source/drain portions. The width of the channel portion of the second transistor is greater than the width of the channel portion of the third transistor. A contact surface between each of the two inner spacers and the channel portion in the second transistor having a dimension in the X direction which is smaller than a dimension in the X direction of a contact surface between each of the two inner spacers and the channel portion in the third transistor.

In accordance with some embodiments of the present disclosure, in each of the first transistors, the second transistor and the third transistor, each of the two source/drain portions includes a group IV semiconductor material, and is doped with group V impurities.

In accordance with some embodiments of the present disclosure, in each of the first transistors, the second transistor and the third transistor, each of the two source/drain portions includes a group IV semiconductor material, and is doped with group III impurities.

In accordance with some embodiments of the present disclosure, in each of the first transistors, the second transistor and the third transistor, each of the two source/drain portions includes a first region disposed to be in contact with the channel portion, and a second region disposed to cover the first region such that the second region is separated from the channel portion. In each of the first transistors, the first region of each of the two source/drain portions overlaps an adjacent one of the two inner spacers in the Z direction to define a first overlap area. In the second transistor, the first region of each of the two source/drain portions overlaps an adjacent one of the two inner spacers in the Z direction to define a second overlap area. In the third transistor, the first region of each of the two source/drain portions overlaps an adjacent one of the two inner spacers in the Z direction to define a third overlap area. The second overlap area is larger than the third overlap area.

In accordance with some embodiments of the present disclosure, the first transistors are coupled to each other to serve as a memory cell capable of storing binary information.

In accordance with some embodiments of the present disclosure, a method for manufacturing a semiconductor structure includes: forming a first patterned structure on a memory region of a base structure and forming a second patterned structure and a third patterned structure on a logic region of the base structure, the logic region being displaced from the memory region, the first patterned structure including a first patterned fin and a first channel portion disposed on and spaced apart from the first patterned fin, the second patterned structure being displaced from the third patterned structure, the second patterned structure including a second patterned fin and a second channel portion disposed on and spaced apart from the second patterned fin, the third patterned structure including a third patterned fin and a third channel portion disposed on and spaced apart from the third patterned fin, each of the first channel portion, the second channel portion and the third channel portion having two end surfaces which are opposite to each other; forming a patterned hard mask covering the first patterned structure and the third patterned structure; performing an etching process through the patterned hard mask so as to reduce a minimum distance between the two end surfaces of the second channel portion; after removing the patterned hard mask, forming two first source/drain portions so that the two first source/drain portions are respectively in contact with the two end surfaces of the first channel portion; after the etching process, forming two second source/drain portions so that the two second source/drain portions are respectively in contact with the two end surfaces of the second channel portion; and after removing the hard mask, forming two third source/drain portions so that the two third source/drain portions are respectively in contact with the two end surfaces of the third channel portion.

In accordance with some embodiments of the present disclosure, the two end surfaces of each of the first channel portion, the second channel portion and the third channel portion are opposite to each other in an X direction.

In accordance with some embodiments of the present disclosure, the first channel portion, the second channel portion and the third channel portion are respectively spaced apart from the first patterned fin, the second patterned fin and the third patterned fin in a Z direction transverse to the X direction. Each of the first channel portion, the second channel portion and the third channel portion has a width in a Y direction transverse to the Z direction. The width of the second channel portion is greater than the width of each of the first channel portion and the third channel portion.

In accordance with some embodiments of the present disclosure, each of the two first source/drain portions, the two second source/drain portions and the two third source/drain portions includes a group IV semiconductor material, and is doped with group V impurities.

In accordance with some embodiments of the present disclosure, each of the two first source/drain portions, the two second source/drain portions and the two third source/drain portions includes a group IV semiconductor material, and is doped with group III impurities.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a first patterned structure on a memory region of a base structure and forming a second patterned structure and a third patterned structure on a logic region of the base structure, the logic region being displaced from the memory region, the first patterned structure including a first patterned fin and a first channel portion disposed on and spaced apart from the first patterned fin, the second patterned structure being displaced from the third patterned structure, the second patterned structure including a second patterned fin and a second channel portion disposed on and spaced apart from the second patterned fin, the third patterned structure including a third patterned fin and a third channel portion disposed on and spaced apart from the third patterned fin, each of the first channel portion, the second channel portion and the third channel portion having two exposed end surfaces which are opposite to each other;
forming a patterned hard mask covering the first patterned structure and the third patterned structure; and
performing an etching process through the patterned hard mask so as to reduce a minimum distance between the two exposed end surfaces of the second channel portion.

2. The method as claimed in claim 1, wherein the two exposed end surfaces of each of the first channel portion, the second channel portion and the third channel portion are opposite to each other in an X direction.

3. The method as claimed in claim 2, wherein
each of the first channel portion, the second channel portion and the third channel portion is spaced apart from a respective one of the first patterned fin, the second patterned fin and the third patterned fin in a Z direction transverse to the X direction,
each of the first channel portion, the second channel portion and the third channel portion has a width in a Y direction transverse to the X direction and the Z direction, and
the width of the second channel portion is greater than the width of each of the first channel portion and the third channel portion.

4. A method for manufacturing a semiconductor structure, comprising:
forming a first patterned structure on a memory region of a base structure and forming a second patterned structure and a third patterned structure on a logic region of the base structure, the logic region being displaced from the memory region, each of the first patterned structure, the second patterned structure and the third patterned structure including
a patterned fin,
a patterned stack disposed on the patterned fin, the patterned stack including a channel portion and a sacrificial portion disposed beneath the channel portion in a Z direction, the channel portion having two channel ends opposite to each other in an X direction transverse to the Z direction,
two inner spacers disposed at two opposite sides of the sacrificial portion in the X direction and disposed beneath the two channel ends of the channel portion in the Z direction, and
a dummy gate portion disposed over the patterned stack and elongated in a Y direction transverse to the X direction and the Z direction, the channel portion having two end surfaces which are opposite to each other in the X direction and which are exposed from the dummy gate portion; and
performing an etching process to selectively recess the two end surfaces of the channel portion in the second patterned structure without recessing the two end surfaces of the channel portion in the third patterned structure.

5. The method as claimed in claim 4, wherein a width of the patterned fin in the second patterned structure in the Y direction is greater than each of a width of the patterned fin in the first patterned structure in the Y direction and a width of the patterned fin in the third patterned structure in the Y direction.

6. The method as claimed in claim 4, wherein, before the etching process, the channel portion in the first patterned structure, the channel portion in the second patterned structure, and the channel portion in the third patterned structure have a same length in the X direction.

7. The method as claimed in claim 4, wherein, after the etching process, a contact surface area between each of the two inner spacers and the channel portion in the second patterned structure is smaller than a contact surface area between each of the inner spacers and the channel portion in the third patterned structure.

8. The method as claimed in claim 4, further comprising:
forming two first source/drain portions respectively at two opposite sides of the dummy gate portion in the first patterned structure such that the channel portion in the first patterned structure extends between the two first source/drain portions;
after the etching process, forming two second source/drain portions respectively at two opposite sides of the dummy gate portion in the second patterned structure such that the channel portion in the second patterned structure extends between the two second source/drain portions; and
forming two third source/drain portions respectively at two opposite sides of the dummy gate portion in the third patterned structure such that the channel portion in the third patterned structure extends between the two third source/drain portions.

9. The method as claimed in claim 8, wherein
formation of each of the two first source/drain portions, the two second source/drain portions and the two third source/drain portions includes
forming a first region in contact with the channel portion in a corresponding one of the first patterned structure, the second patterned structure and the third patterned structure, and
forming a second region to cover the first region such that the second region is separated from the channel portion in the corresponding one of the first patterned structure, the second patterned structure and the third patterned structure,
in the first patterned structure, the first region of each of the two first source/drain portions overlaps an adjacent one of the two inner spacers in the Z direction to define a first overlap area,
in the second patterned structure, the first region of each of the two second source/drain portions overlaps an adjacent one of the two inner spacers in the Z direction to define a second overlap area,
in the third patterned structure, the first region of each of the two third source/drain portions overlaps an adjacent one of the two inner spacers in the Z direction to define a third overlap area, and
the second overlap area is larger than the third overlap area.

10. The method as claimed in claim 9, wherein the second overlap area is larger than the first overlap area.

11. The method as claimed in claim 8, wherein each of the two first source/drain portions, the two second source/drain portions and the two third source/drain portions includes a group IV semiconductor material, and is doped with group V impurities.

12. The method as claimed in claim 8, wherein each of the two first source/drain portions, the two second source/drain portions and the two third source/drain portions includes a group IV semiconductor material, and is doped with group III impurities.

13. The method as claimed in claim 8, wherein the dummy gate portion includes a dummy gate and two spacers located at two opposite sides of the dummy gate in the X direction.

14. The method as claimed in claim 13, further comprising, after formation of the two first source/drain portions, the two second source/drain portions and the two third source/drain portions:
removing the dummy gate and the sacrificial portion in each of the first patterned structure, the second patterned structure and the third patterned structure.

15. The method as claimed in claim 14, further comprising, after removing the dummy gate and the sacrificial portion:
forming a gate dielectric layer around the channel portion in each of the first patterned structure, the second patterned structure and the third patterned structure; and
forming a gate electrode on the gate dielectric layer in each of the first patterned structure, the second patterned structure and the third patterned structure.

16. A semiconductor structure, comprising:
first transistors disposed on a memory region of a substrate, and a second transistor and a third transistor disposed on a logic region of the substrate, each of the first transistors, the second transistor and the third transistor including
two source/drain portions spaced apart from each other in an X direction,
a channel portion extending between the two source/drain portions in the X direction to terminate at two channel ends, and having a width in a Y direction transverse to the X direction,
a gate electrode elongated in the Y direction, and disposed around the channel portion, and
two inner spacers disposed beneath the two channel ends of the channel portion so as to separate the gate electrode from the two source/drain portions,
the width of the channel portion of the second transistor being greater than the width of the channel portion of the third transistor,
a contact surface between each of the two inner spacers and the channel portion in the second transistor having a dimension in the X direction which is smaller than a dimension in the X direction of a contact surface between each of the two inner spacers and the channel portion in the third transistor.

17. The semiconductor structure as claimed in claim 16, wherein in each of the first transistors, the second transistor and the third transistor, each of the two source/drain portions includes a group IV semiconductor material, and is doped with group V impurities.

18. The semiconductor structure as claimed in claim 16, wherein in each of the first transistors, the second transistor and the third transistor, each of the two source/drain portions includes a group IV semiconductor material, and is doped with group III impurities.

19. The semiconductor structure as claimed in claim 16, wherein
in each of the first transistors, the second transistor and the third transistor, each of the two source/drain portions includes a first region disposed to be in contact with the channel portion, and a second region disposed to cover the first region such that the second region is separated from the channel portion,
in each of the first transistors, the first region of each of the two source/drain portions overlaps an adjacent one of the two inner spacers in the Z direction to define a first overlap area,
in the second transistor, the first region of each of the two source/drain portions overlaps an adjacent one of the two inner spacers in the Z direction to define a second overlap area,
in the third transistor, the first region of each of the two source/drain portions overlaps an adjacent one of the two inner spacers in the Z direction to define a third overlap area, and
the second overlap area is larger than the third overlap area.

20. The semiconductor structure as claimed in claim 16, wherein the first transistors are coupled to each other to serve as a memory cell capable of storing binary information.
